(19) United States
(12) Patent Application Publication
(10) Pub. No.: US 2011/0047325 A1
(43) Pub. Date: Feb. 24, 2011

(54) NONVOLATILE SEMICONDUCTOR MEMORY DEVICE AND SIGNAL PROCESSING SYSTEM

(75) Inventor: Satoshi MISHIMA, Osaka (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/938,079

(22) Filed: Nov. 2, 2010

Related U.S. Application Data
(63) Continuation of application No. PCT/JP2009/000290, filed on Jan. 27, 2009.

(30) Foreign Application Priority Data
Jun. 10, 2008 (JP) 2008-151307

(51) Int. Cl. G06F 12/00; G11C 16/04

(52) U.S. Cl. 711/103; 365/185.03; 711/E12.008

(57) ABSTRACT

A nonvolatile semiconductor memory device includes: memory cells regularly arranged in a matrix pattern, and having as a charge storage medium a nonconductive nitride film capable of configuring two physical bits in each memory cell; and bit lines connecting in common a source or drain of one of two memory cells adjoining in a row direction with a source or drain of the other memory cell. One of two bits in each memory cell having the nonconductive nitride film is accessed by a first address group allocated to a first function, and the other bit is accessed by a second address group allocated to a second function.

### CROSS-REFERENCE TO RELATED APPLICATION

This is a continuation of PCT International Application PCT/JP2009/000290 filed on Jan. 27, 2009, which claims priority to Japanese Patent Application No. 2008-151307 filed on Jun. 10, 2008. The disclosures of these applications including the specifications, the drawings, and the claims are hereby incorporated by reference in its entirety.

### BACKGROUND

The present disclosure relates to nonvolatile semiconductor memory devices and signal processing systems provided with the same, and more particularly to a technique that is effective when applied to systems for storing data for a plurality of different function applications in the nonvolatile semiconductor memory devices.

Nonvolatile semiconductor memory devices are increasingly used in applications such as information systems and communication systems due to their ability to retain stored information even after the power is off. There is a growing demand for flash electrically erasable programmable read only memories (flash EEPROMs, flash memories), as full array erasure (an erase operation in which the entire chip is erased) or block erasure (an erase operation in which the memory is erased in blocks) is performed in the flash EEPROMs, and thus a smaller memory cell size and lower cost can be achieved.

In recent years, floating gate (FG) flash memories using polysilicon as a charge storage medium as shown in FIG. 1 are increasingly replaced with flash memories using a silicon nitride film (hereinafter referred to as the nitride film) as a charge storage medium, namely flash memories called “metal oxide nitride oxide semiconductor (MONOS) or silicon oxide nitride oxide semiconductor (SONOS) flash memories.” In the FG flash memories, defects in a tunnel oxide film serve as leakage sources, which degrade charge retention characteristics. Thus, reduction in thickness of the tunnel oxide film is limited in terms of size reduction. On the other hand, the MONOS flash memories are structured to locally store charges in traps in the nitride film. Thus, even if defects are produced in part of the tunnel oxide film, such defects cannot serve as leakage sources of all the charges. Moreover, the MONOS flash memories, if successfully controlled, are capable of locally storing charges, and thus are capable of storing two physical bits in one memory cell transistor. Accordingly, there are high expectations for reduction in size as the MONOS flash memories can implement reliable, high capacity nonvolatile semiconductor memories.

FIG. 2 conceptually illustrates write and erase operations of a MONOS flash memory capable of storing two physical bits in one memory cell transistor. In the write operation, electrons excited by applying a positive voltage (Vg>0 V) to the gate electrode change to channel hot electrons (CHEs) near the drain. The CHEs pass through the tunnel oxide film, and are trapped in a first bit in the nitride film. In the write operation to a second bit, CHEs are similarly trapped with the source and the drain switched in position. In the erase operation, a negative voltage (Vg<0 V) is applied to the gate electrode, and hot holes (HHs) generated near the drain pass through the tunnel oxide film to neutralize the electrons stored in the first bit. In the erase operation of the second bit, the electrons in the second bit are similarly neutralized with the source and the drain switched in position. That is, in the case of storing two physical bits in one memory cell transistor, the erase operation is characterized by erasing the two locally stored bits independently rather than erasing them at a time. It is also possible to use a Fowler-Nordheim (FN) tunneling current to perform the write and erase operations, but hot carriers are typically used as the voltages required for the write and erase operations can be reduced. Thus, MONOS flash memories are increasingly used in the art.

Flash memories are used in various applications. For example, in signal processing systems as represented by mobile phones, data that is handled by the flash memories are classified into code applications (programs; alternatively referred to as program applications) and data applications. Codes are programs that are executed by an arithmetic processing unit in a system large-scale integration (LSI) circuit, and functions or capabilities to read codes that are needed by the arithmetic processing unit are required for the code applications. Functions or capabilities to write and read a large amount of data within a required time are required for the data applications such as images which are handled by application software that is executed by the system LSI circuit. Conventionally, flash memories (mainly FG flash memories) play a role in the systems of mobile phones. Specifically, NOR flash memories are used as flash memories for code applications, and NAND flash memories are used as flash memories for data applications. However, as the capabilities and capacity of the mobile phones increase, it is increasingly difficult to place in the mobile phones a two-chip configuration having a NOR flash memory chip and a NAND flash memory chip as shown in FIG. 3A. Thus, it is necessary to integrate the two chips into one chip, and to reduce the area of the chip to achieve cost reduction. Thus, flash memories are needed which are capable of meeting different performance needs by one chip.

Other applications of the flash memories include, e.g., memory card systems in which a NAND flash memory and a microcontroller are placed in one package. The capacity of such memory card systems is becoming increasingly large mainly for the data applications (such as character data, music/video data, and backup data). In order to maintain reliability, the memory card systems are provided with redundant memory blocks or an error correction circuit for increased data reliability, are provided with a wear leveling function to evenly distribute rewrite cycles among blocks in file systems of the flash memories, or are provided with a function called “reclamation” to refresh invalid blocks. However, providing an increased number of functions complicates control of blocks by the system, and also increases the amount of data to be handled at a time, thereby increasing the time it takes to perform the write operation. This causes problems regarding backup operations in the event that the power is shut off while executing the operation.

As described above, a technique is needed which is capable of handling, in a simple manner, a flash memory having an ever increasing capacity and an ever increasing number of functions by one chip.

One-chip techniques have been implemented as shown in FIGS. 3B-3C. One of the one-chip techniques is a system-in-package (SIP) technique, which is a technique of placing a plurality of chips in one package (FIG. 3C). This technique reduces the mounting area as a NOR flash memory and a NAND flash memory are integrated into one chip. However, this technique does not reduce complexity of system control, and cannot reduce the cost due to the complex assembly process. Another one-chip technique is a system-on-chip (SOC) technique (FIG. 3B). This technique implements, in one chip, a random access capability required for the code applications, and a high-speed read operation and a continuous sequential access capability required for the data applications.

Japanese Patent Publication Nos. H10-326493, 2004-273117, and H07-281952 disclose a technique regarding sectorization of a code storage memory portion and a data storage memory portion, a technique that enables a code storage memory portion to be read while writing or erasing a data storage memory portion, and a technique of providing a plurality of memory blocks capable of operating independently of each other. These techniques are effective in reducing complexity of the system and reducing the mounting area. However, the chip area is increased due to enhanced functions and increased capacity of the systems, and providing separate blocks for the functions causes a chip area loss by column decoders and memory element isolation layers.

Japanese Patent No. 3,519,940 discloses a technique that fulfills different performance needs by varying the application time of a write voltage to memory cells in the SOC technique. Japanese Patent No. 3,519,940 discloses that since required read endurance is different between a program region and a data region, a write voltage is applied to the data region for a shorter period than a write voltage to the program region to increase the endurance. Whether a region to be accessed is the program region or the data region is determined by an input address. In the configuration of Japanese Patent No. 3,519,940, if the program region and the data region are present in the same sector, data of the other region needs to be saved when erasing data of one of the program region and the data region by the system. Thus, the program region and the data region need to be provided in separate blocks as units of erasure. Saving the data of the other region not only increases the number of extra blocks, but also complicates system control. Moreover, providing separate blocks causes a chip area loss by column decoders and memory element isolation layers.

### SUMMARY

As described in the background art, the techniques that implement different functions or capabilities in one chip are disclosed. However, since such different functions or capabilities need to be able to be controlled independently by the system, it is necessary to provide different functions or capabilities in separate sectors or blocks. This not only causes a chip area loss by decoders and memory element isolation layers, but also complicates the system.

In order to solve the above problems, a nonvolatile semiconductor memory device according to the present invention includes: memory cells regularly arranged in a matrix pattern, and having as a charge storage medium a nonconductive nitride film capable of configuring two physical bits in each memory cell; and bit lines connecting in common a source or drain of one of two memory cells adjoining in a row direction with a source or drain of the other memory cell. One of two bits in each memory cell having the nonconductive nitride film is accessed by a first address group allocated to a first function, and the other bit is accessed by a second address group allocated to a second function.

According to the present invention, in the same sector or the same block that is a unit of erasure, data of different functions/applications is allocated to two physical bits capable of being independently addressed. Since one bit and the other bit in each memory cell are erased independently, no data interference occurs therebetween. Thus, different functions or capabilities can be implemented in the same sector or the same block, whereby a reliable nonvolatile semiconductor memory device capable of simplifying system control can be provided.

In a system using the nonvolatile semiconductor memory device of the present invention, nonvolatile semiconductor memory devices that are conventionally formed in a plurality of chips can be formed in one chip. Thus, the mounting area can be reduced, and the cost, power consumption, and resources of the system can be reduced by the one-chip configuration while increasing the capacity and reliability by the MONOS multi-bit configuration.

### BRIEF DESCRIPTION OF THE DRAWINGS

FIG. 1 is a diagram comparing an FG structure with a MONOS structure.

FIG. 2 is a conceptual diagram of write and erase operations of the MONOS structure.

FIGS. 3A, 3B, and 3C are schematic diagrams showing the configurations of typical signal processing systems of mobile phones.

FIG. 4 is a conceptual diagram of a nonvolatile semiconductor memory according to an embodiment of the present invention.

FIG. 5 is a schematic diagram showing the configuration of a nonvolatile semiconductor memory device according to a first embodiment of the present invention.

FIG. 6 is a schematic diagram showing the configuration of a nonvolatile semiconductor memory device according to a second embodiment of the present invention.

FIG. 7 is a schematic diagram showing the configuration of a nonvolatile semiconductor memory device according to a third embodiment of the present invention.

FIG. 8 is a schematic diagram illustrating a method for adjusting the implantation concentration of impurity ions according to a fourth embodiment of the present invention.

FIG. 9 is a schematic diagram showing the configuration of a nonvolatile semiconductor memory device according to a fifth embodiment of the present invention.

FIG. 10 is a schematic diagram showing the configuration of a signal processing system according to a sixth embodiment of the present invention.

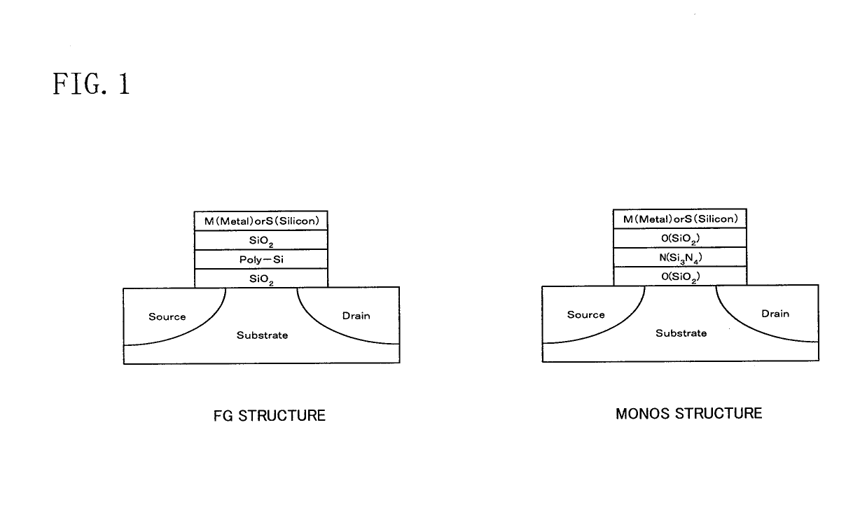

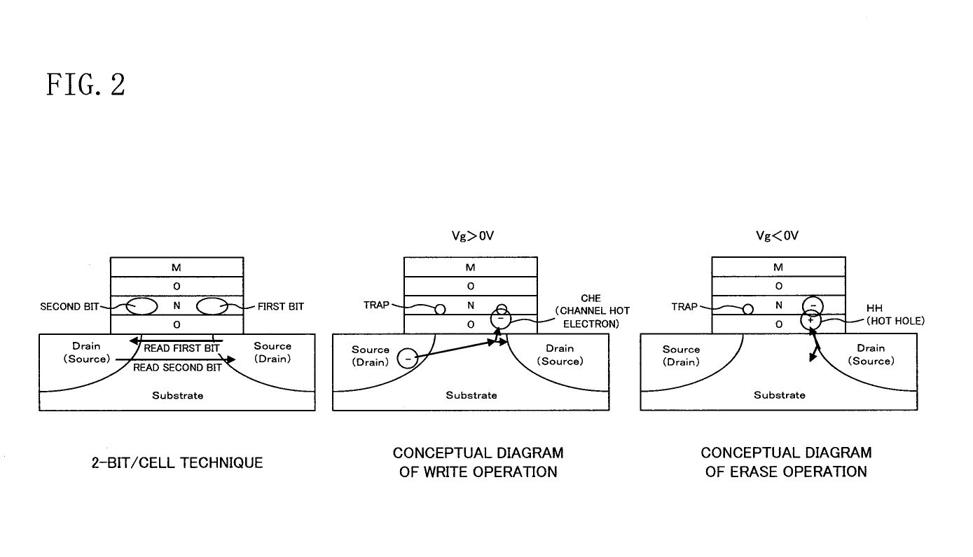

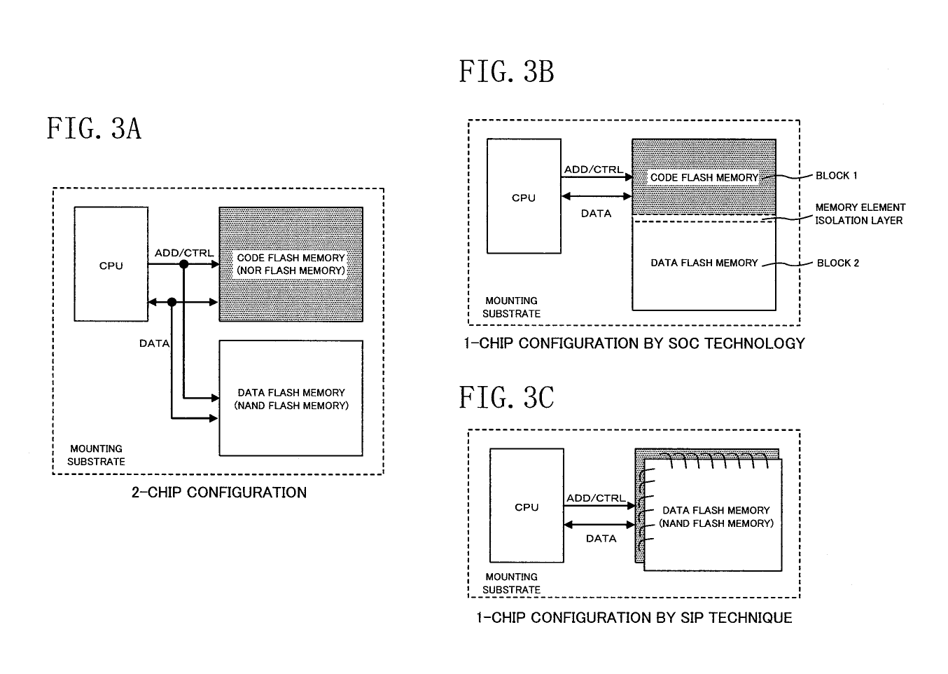

### DETAILED DESCRIPTION

Embodiments of the present invention will be described below with reference to the accompanying drawings. Note that in the following embodiments, components having similar functions to those of other embodiments are denoted by the same reference characters.

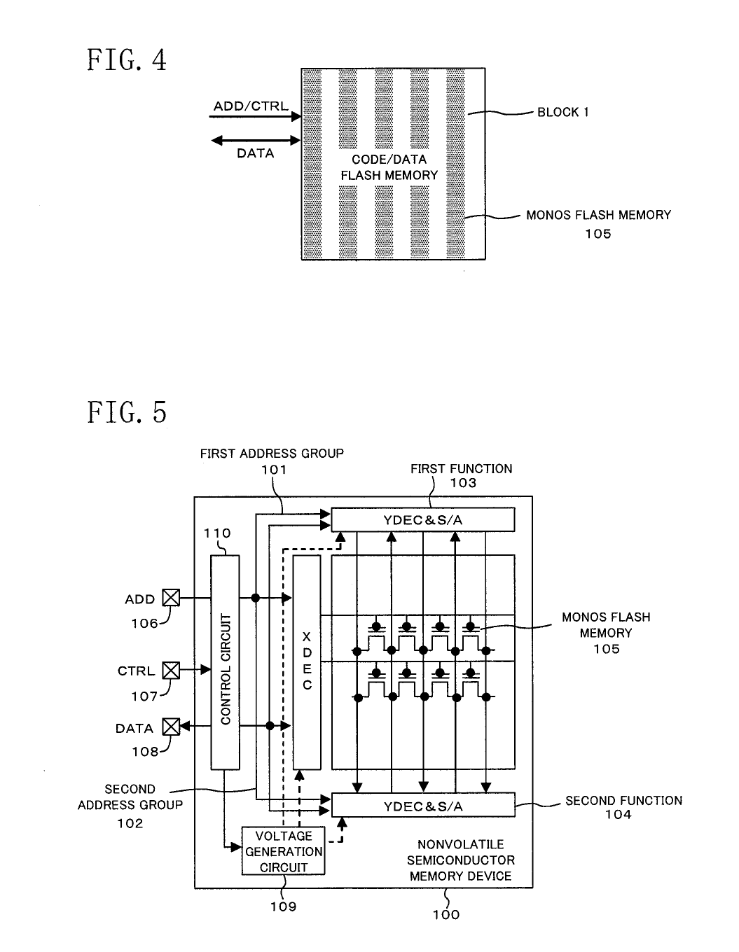

FIG. 4 is a conceptual diagram of a nonvolatile semiconductor memory according to an embodiment of the present invention. This nonvolatile semiconductor memory is a MONOS flash memory (105), in which two bits in each memory cell are allocated to code applications and data applications in the same block, respectively, and are controlled by addresses. In this manner, different functions or capabilities are implemented by address control in a one-chip configuration. This can reduce the need for decoder circuits and memory element isolation, whereby the chip area can be reduced.

### First Embodiment

FIG. 5 shows a nonvolatile semiconductor memory device according to a first embodiment of the present invention. This nonvolatile semiconductor memory device (100) accesses a MONOS flash memory cell array (105) while controlling a voltage generation circuit (109) via a control circuit (110) by inputs/outputs of an external address terminal (106), an external control terminal (107), and an external data terminal (108). If an input address is an address of a first address group (101), one of the two bits of each memory cell in the MONOS flash memory (105) is accessed via a first function (103) connected thereto. If the input address is an address of a second address group (102), the other bit of each memory cell in the MONOS flash memory (105) is accessed via a second function (104) connected thereto. Thus, operations of the different functions can be performed according to the input address.

### Second Embodiment

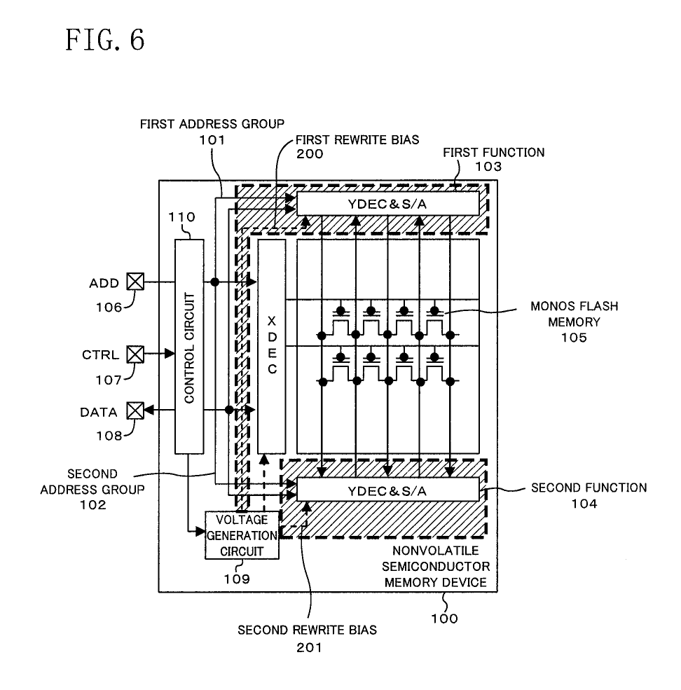

FIG. 6 shows a nonvolatile semiconductor memory device according to a second embodiment of the present invention. This nonvolatile semiconductor memory device (100) shows a configuration example in which the voltage application method is varied between the first function (103) and the second function (104).

In this example, the first function (103) and the second function (104) change the rewrite speed. The control circuit (110) determines whether an input address is an address of the first address group (101) or the second address group (102), and the voltage generation circuit (109) applies a first rewrite voltage (200) to the first function (103) to which the first address group (101) is connected, and applies a second rewrite voltage (201) to the second function (104) to which the second address group (102) is connected.

In the case where a high speed rewrite operation is desired for the first function (103), and long read endurance is desired for the second function (104), the voltage generation circuit (109) generates a higher voltage as the first rewrite bias (200) than the second rewrite bias (201). Thus, the first function (103) serves as a function to cause the memory cell to reach a rewrite level more quickly, whereby the flash memory having different rewrite speeds in the same block can be implemented.

In the bits of the memory cells of the second address group (102) that is handled by the second function (104), damage to an oxide film caused by rewrite operations can be reduced, whereby the MONOS flash memory (105) can be used as a flash memory having satisfactory data retention characteristics.

Note that if the high voltage as the first rewrite bias (200) of the first function (103) is a problem, this problem is reduced by outputting pulses (such as step pulses), whose voltage level and application time are controlled, from the voltage generation circuit (109) as the first rewrite bias (200).

According to the configuration of the present embodiment, a flash memory having a function to provide a high rewrite speed and a capability to provide long read endurance can be implemented by one chip without partitioning a single block into multiple areas for different speeds and endurances.

### Third Embodiment

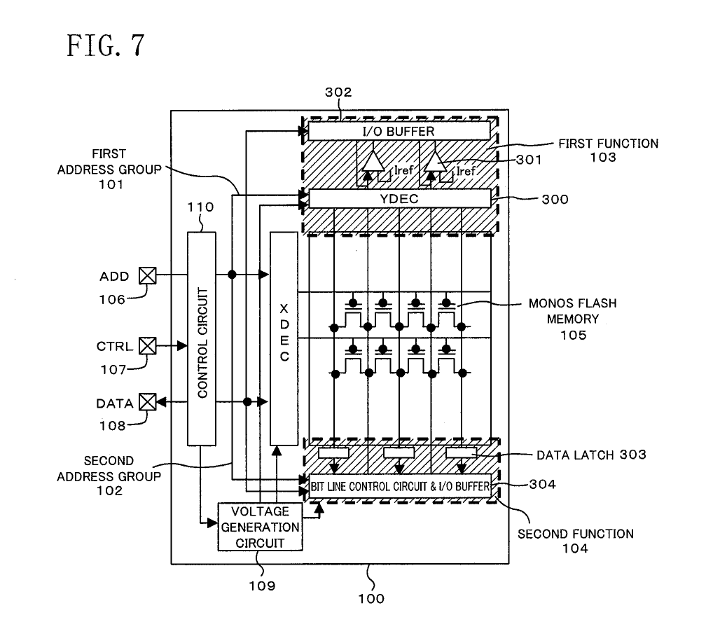

FIG. 7 shows a nonvolatile semiconductor memory device according to a third embodiment of the present invention. This nonvolatile semiconductor memory device (100) shows a configuration example in which a data input/output (I/O) configuration from the memory cell array (105) in the first function (103) is different from that from the memory cell array (105) in the second function (104), so that different functions can be implemented.

In this example, the first function (103) is a random access configuration that is used for code applications, and the second function (104) is a continuous sequential access configuration that is commonly used for data applications.

In the configuration of the first function (103), bit lines that are connected to some bits of the memory cells in the MONOS flash memory (105) are connected to a column decoder (300), and are connected to an input/output (I/O) buffer (302) via sense amplifiers (301). This is an I/O circuit of a typical NOR flash memory.

In the configuration of the second function (104), bit lines that are connected to the other bits of the memory cells in the MONOS flash memory (105) are connected to data latch circuits (303), and are connected to an I/O buffer (304) via a bit line control circuit (304). This is an I/O circuit of a typical NAND flash memory.

If an address that is used for the code applications is designated, the first function (103) is activated by the first address group (101) via the control circuit (110), and a random access read operation or the like is performed. On the other hand, if an address that is used for the data applications is designated, the second function (104) is activated by the second address group (102) via the control circuit (110), and a continuous sequential access read operation or the like is performed.

As described above, since the I/O circuit configuration in the first function (103) can be different from that in the second function (104), data can be handled in the manners that are characteristic of the NOR flash memory and the NAND flash memory.

According to the configuration of the present embodiment, as viewed from the system side, data of the flash memory can be handled in one chip without partitioning the block into multiple areas for performing random access and continuous sequential access, which are characteristic of the NOR flash memory and the NAND flash memory.

### Fourth Embodiment

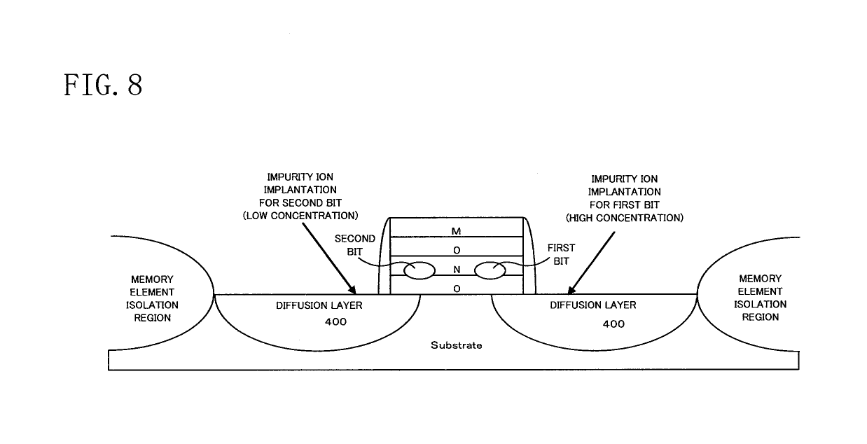

A fourth embodiment of the present invention shows an example of a manufacturing method in which the memory cells are formed so that the first function (103) and the second function (104) provide different capabilities for one bit and the other bit in each memory cell. This manufacturing method will be described below with reference to FIG. 8.

In a typical process of forming a memory cell transistor, write characteristics can be varied between the two bits in each memory cell by controlling the implantation concentration of impurity ions in diffusion layers (400) as a source and a drain.

For example, a high concentration of impurity ions is implanted to the first bit side, and a low concentration of impurity ions is implanted to the second bit side. In this case, a higher electric field is generated near the drain for the first bit than for the second bit in the write operation, and thus a larger number of channel hot electrons are generated for the first bit, whereby an efficient, high speed write operation can be implemented.

If a high speed write operation is required, a large number of rewrite operations are often required, and data retention characteristics are not strictly required. Thus, for the second bit for which the high speed write operation is not required, a low concentration of impurity ions is implanted so that a high electric field is not applied and damage is reduced. The high speed write capability and the capability of data retention characteristics with extended lifetime can be provided in this manner.

The thickness of the tunnel oxide film also affects the rewrite speed. The energy barrier for hot carriers to pass through increases as the tunnel oxide film increases. Thus, the rewrite speed is reduced, but the data retention characteristics are improved. The thickness of the tunnel oxide film in the first and second bits can be controlled by, e.g., adjusting the angle of a chemical vapor deposition (CVD) process when forming the tunnel oxide film.

As described above, by providing the first function (103) and the second function (104) when forming the memory cells, a flash memory having a high rewrite speed and long read endurance can be implemented in one chip without providing the first function (103) and the second function (104) in separate blocks.

### Fifth Embodiment

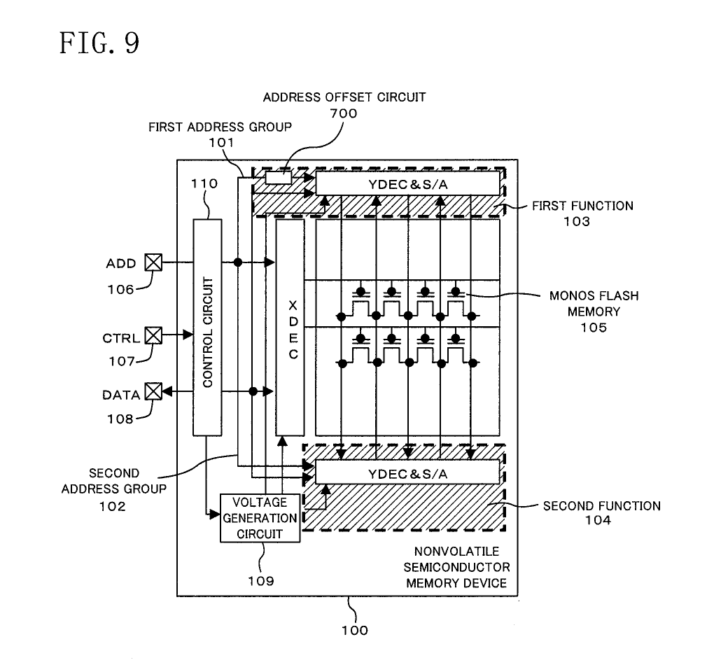

FIG. 9 shows a nonvolatile semiconductor memory device according to a fifth embodiment of the present invention. This nonvolatile semiconductor memory device (100) shows a configuration example in which the first function (103) complements data written by the second function (104).

The first function (103) is configured as a function to write to a first address region the same data as that to a second address region while a write operation is being performed to the second address region, by using an address offset circuit (700) that inhibits access to a specific memory cell designated by a second address group (102), and memory cells adjoining the specific memory cell.

Thus, even if data for code applications, which is important to the system operation, is lost due to unexpected circumstances such as an unexpected power-off condition, the lost data can be restored by reading the data written by the first function (103).

As another configuration example, data that reduces data interference in the same memory cell may be written by the first function (103) to increase the endurance of data written by the second function (104), whereby data reliability can be increased.

### Sixth Embodiment

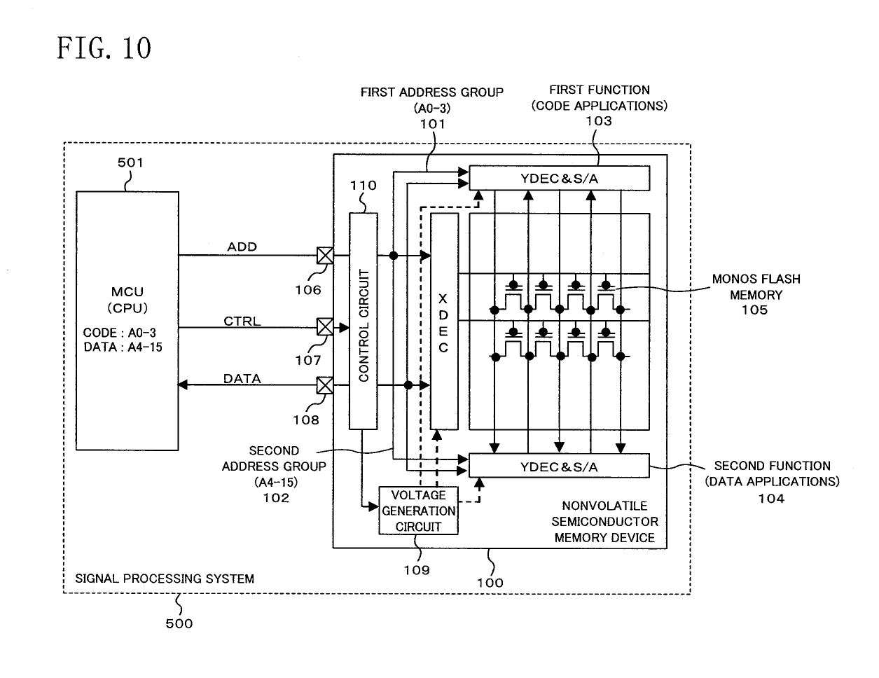

FIG. 10 shows a signal processing system according to a sixth embodiment of the present invention. This signal processing system (500) includes the nonvolatile semiconductor memory device (100) and a microcontroller (501). In this example, it is assumed that the first function (103) is allocated to code applications, and the second function (104) is allocated to data applications. The microcontroller (501) can be operated as a signal processing system (500) capable of switching and handling the code applications and the data applications by designating an address region for the code applications and an address region for the data applications, which have already been determined in the nonvolatile semiconductor memory device (100). Thus, a signal processing system can be provided which is capable of performing simple system control with a small chip size.

As described above, the nonvolatile semiconductor memory device and the signal processing system according to the present invention can reduce power consumption, cost, and resources due to a small mounting area by the one-chip configuration, and can be utilized as a technique capable of simplifying the system when integrating nonvolatile semiconductor memory devices that are required to have a plurality of different capabilities. Moreover, the system can reconfigure the functions of the nonvolatile semiconductor memory device by providing the first function (103) and the second function (104) as a plurality of functions blocks, and switching the function blocks by selection signals. The capacity of the nonvolatile semiconductor memory device can further be increased by replacing each of the two bits of the MONOS with a unit cell capable of defining levels more than two by utilizing multi-level cell (MLC) techniques. Moreover, by independently synchronizing the first address group (101) and the second address group (102) with the rises and falls of a system clock signal in a 2-bit access method, different functions can be simultaneously executed without interfering each other in the access to the same block.

What is claimed is:

1. A nonvolatile semiconductor memory device, comprising:
memory cells regularly arranged in a matrix pattern, and having as a charge storage medium a nonconductive nitride film capable of configuring two physical bits in each memory cell; and
bit lines connecting in common a source or drain of one of two memory cells adjoining in a row direction with a source or drain of the other memory cell, wherein
one of two bits in each memory cell having the nonconductive nitride film is accessed by a first address group allocated to a first function, and the other bit is accessed by a second address group allocated to a second function.

2. The nonvolatile semiconductor device of claim 1, wherein
a voltage that is applied to the first function is different from a voltage that is applied to the second function.

3. The nonvolatile semiconductor device of claim 1, wherein
a data input/output configuration from a memory cell array in the first function is different from that from the memory cell array in the second function.

4. The nonvolatile semiconductor device of claim 1, wherein
the first function is a function to complement data written by the second function.

5. The nonvolatile semiconductor device of claim 1, wherein
the memory cells of the nonvolatile semiconductor memory device are formed so that the first function and the second function provide different capabilities for one bit and the other bit in each memory cell.

6. A signal processing system, comprising:
the nonvolatile semiconductor memory device of claim 1; and
a microcontroller, wherein
the microcontroller is capable of controlling the first function and the second function by the first address group and the second address group.
